(19) United States
(12) Patent Application Publication
(10) Pub. No.: US 2026/0293738 A1
(43) Pub. Date: Sep. 24, 2026

(54) UNDERFILL ADHESIVE FLOW CONTROL USING DAM STRUCTURE

(71) Applicant: QUALCOMM Incorporated, San Diego, CA (US)

(72) Inventors: Tae Wan KIM, San Diego, CA (US); Jaekyu SONG, San Diego, CA (US); Rajneesh KUMAR, San Diego, CA (US)

(21) Appl. No.: 19/084,336

(22) Filed: Mar. 19, 2025

(51) Int. Cl. H01L 23/00; H01L 21/56; H01L 23/31; H01L 25/07

(52) U.S. Cl. CPC H10W 72/30; H10W 72/073; H10W 72/07302; H10W 72/07311; H10W 72/07338; H10W 72/20; H10W 72/387; H10W 72/851; H10W 74/012; H10W 74/141; H10W 74/15; H10W 90/00; H10W 90/724; H10W 90/734

(57) ABSTRACT

Disclosed are semiconductor packages. In one or more aspects, a dam support may be provided on a substrate of a semiconductor package. The dam support may be placed on edge of the saw street of the semiconductor package. In this way, underfill undercut can be minimized or even prevented altogether.

### BACKGROUND OF THE DISCLOSURE

### 1. Field of the Disclosure

This disclosure relates generally to die packages or modules, and more specifically, but not exclusively, to underfill adhesive flow control using dam structure in semiconductor packages and fabrication techniques thereof.

### 2. Description of the Related Art

Integrated circuit (IC) technology has achieved great strides in advancing computing power through miniaturization of active components. There is a push for smaller semiconductor packages size, such as in side-by-side (SXS) package with exposed die structures, requiring narrow die (e.g., DRAM) to package keep-out-zone (KOZ). Current SXS packages require underfill (UF) to have better reflow (REL) stability. However, with conventional underfill bleed out control limitation, underfill undercut is inevitable. Accordingly, there is a need for systems, apparatus, and methods that overcome the deficiencies of conventional semiconductor packages including the methods, system and apparatus provided herein.

### SUMMARY

The following presents a simplified summary relating to one or more aspects and/or examples associated with the apparatus and methods disclosed herein. As such, the following summary should not be considered an extensive overview relating to all contemplated aspects and/or examples, nor should the following summary be regarded to identify key or critical elements relating to all contemplated aspects and/or examples or to delineate the scope associated with any particular aspect and/or example. Accordingly, the following summary has the sole purpose to present certain concepts relating to one or more aspects and/or examples relating to the apparatus and methods disclosed herein in a simplified form to precede the detailed description presented below.

An exemplary semiconductor package is disclosed. The semiconductor package may comprise a die on a substrate. The semiconductor package may also comprise an underfill (UF) between the die and the substrate. The semiconductor package may further comprise a dam support on the substrate and on a side of the underfill. The semiconductor package may yet comprise a mold on the underfill and the dam support. The mold may encapsulate sides of the die. Also, sides of the dam support, the substrate, and the mold may define a side of the semiconductor package.

A method of fabricating a semiconductor package is disclosed. The method may comprise providing a die on a substrate. The method may also comprise forming an underfill (UF) between the die and the substrate. The method may further comprise forming a dam support on the substrate and on a side of the underfill. The method may yet comprise forming a mold on the underfill and the dam support. The mold may encapsulate sides of the die. Also, sides of the dam support, the substrate, and the mold may define a side of the semiconductor package.

Other objects and advantages associated with the aspects disclosed herein will be apparent to those skilled in the art based on the accompanying drawings and detailed description.

### BRIEF DESCRIPTION OF THE DRAWINGS

The accompanying drawings are presented to aid in the description of various aspects of the disclosure and are provided solely for illustration of the aspects and not limitation thereof.

FIG. 1 illustrates a cross-sectional view of a conventional semiconductor package.

FIGS. 2A-2B illustrate cross-sectional views of a semiconductor package prior to and after singulation in accordance with one or more aspects of the disclosure.

FIGS. 3A-3B illustrate cross-sectional views of another semiconductor package prior to and after singulation in accordance with one or more aspects of the disclosure.

FIG. 4 illustrates a flow of fabrication steps to fabricate a semiconductor package in accordance with one or more aspects of the disclosure.

FIGS. 5-7 illustrate flow charts of example methods of manufacturing a semiconductor package in accordance with at one or more aspects of the disclosure.

FIG. 8 illustrates various electronic devices which may utilize one or more aspects of the disclosure.

Other objects and advantages associated with the aspects disclosed herein will be apparent to those skilled in the art based on the accompanying drawings and detailed description. In accordance with common practice, the features depicted by the drawings may not be drawn to scale. Accordingly, the dimensions of the depicted features may be arbitrarily expanded or reduced for clarity. In accordance with common practice, some of the drawings are simplified for clarity. Thus, the drawings may not depict all components of a particular apparatus or method. Further, like reference numerals denote like features throughout the specification and figures.

### DETAILED DESCRIPTION

Disclosed are semiconductor packages and methods for fabricating the same. In an aspect, The semiconductor package may comprise a die on a substrate. The semiconductor package may also comprise an underfill (UF) between the die and the substrate. The semiconductor package may further comprise a dam support on the substrate and on a side of the underfill. The semiconductor package may yet comprise a mold on the underfill and the dam support. The mold may encapsulate sides of the die. Also, the dam support, the substrate, and the mold may define a side of the semiconductor package. This can minimize or prevent altogether underfill undercut problem.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Those of skill in the art will appreciate that the information and signals described below may be represented using any of a variety of different technologies and techniques. For example, data, instructions, commands, information, signals, bits, symbols, and chips that may be referenced throughout the description below may be represented by voltages, currents, electromagnetic waves, magnetic fields or particles, optical fields or particles, or any combination thereof, depending in part on the particular application, in part on the desired design, in part on the corresponding technology, etc.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, the sequence(s) of actions described herein can be considered to be embodied entirely within any form of non-transitory computer-readable storage medium having stored therein a corresponding set of computer instructions that, upon execution, would cause or instruct an associated processor of a device to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

In certain described example implementations, instances are identified where various component structures and portions of operations can be taken from known, conventional techniques, and then arranged in accordance with one or more exemplary embodiments. In such instances, internal details of the known, conventional component structures and/or portions of operations may be omitted to help avoid potential obfuscation of the concepts illustrated in the illustrative embodiments disclosed herein.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof.

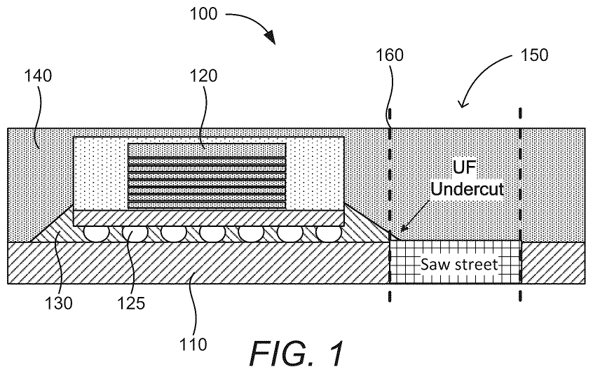

FIG. 1 illustrates a cross-sectional view of a conventional semiconductor package 100. The conventional semiconductor package 100 includes a substrate 110 and a die 120 on the substrate 110. Underfill (UF) 130 fills the space between the die 120 and substrate 110 not occupied by die bumps 125. A mold 140 is on and encapsulates the underfill 170 and the die 120.

FIG. 1 illustrates the semiconductor package 100 before being singulated. During singulation, the substrate is cut along a saw street 150. The singulation results in the side 160 of the semiconductor package 100 being formed. Note that some of the underfill 130 is on the saw street 150 prior to the singulation. Then when the singulation occurs, the underfill 130 is undercut, which compromises the mechanical integrity of the semiconductor package 100.

As mentioned above, there is a push for smaller semiconductor packages size, such as in side-by-side (SXS) package with exposed die structures, requiring narrow die (e.g., DRAM) to package keep-out-zone (KOZ). As the KOZ requirements become more stringent, the undercutting of the underfill 130 becomes more and more likely, perhaps even inevitable.

To address these and other issues of the conventional semiconductor package, it is proposed to create a dam structure around the saw street region where the underfill undercut occurs. This can improve underfill stability after singulation, and can enhance overall mechanical integrity of the package.

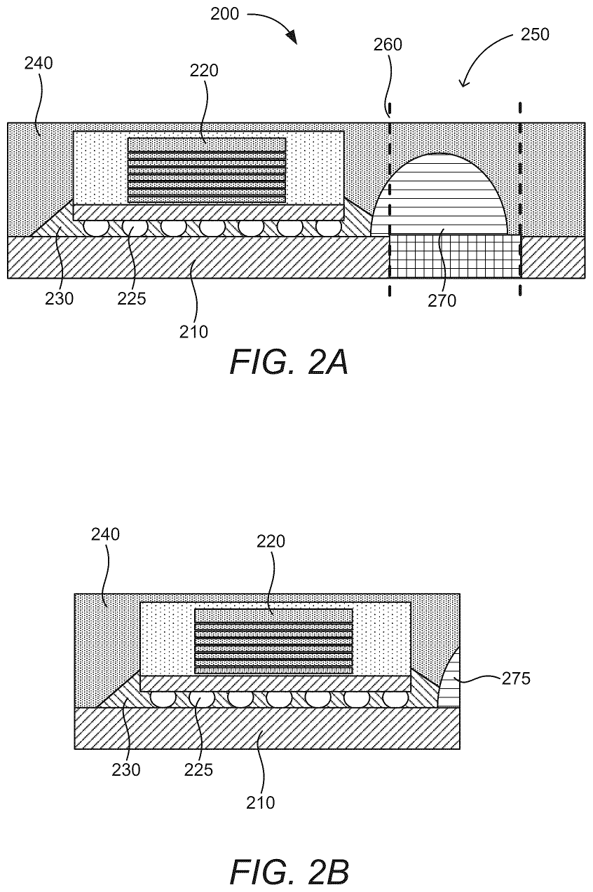

FIG. 2A illustrates a cross-sectional view of a semiconductor package 200 prior to singulation and FIG. 2B illustrates a cross-sectional view of the same semiconductor package 200 after singulation. As seen, the semiconductor package 200 may include a die 220 on a substrate 210. The die 220 may be any type of die such as SoC die, a memory (e.g., DRAM) die, etc. The die 220 may include one or more die bumps 225 on a lower surface thereof for electrically connecting the die 220 with the substrate 210. Underfill 230 may fill the space between the die 220 and substrate 210 not occupied by the die bumps 225. In an aspect, the underfill 230 may be a capillary underfill, e.g., formed from epoxy resin. The capillary underfill may also include a hardener, a filler (e.g., SiO₂ filler), and additives including flexible and adhesion promoter.

A dam material 270 may be formed adjacent to the die 220. As seen, prior to singulation (as seen in FIG. 2A), the dam material 270 may be formed on the substrate 210 in both the region of the saw street 250 as well as the region of the semiconductor package 200. After singulation (as seen in FIG. 2B), the dam material that remains in the region of the semiconductor package 200 may become a dam support 275. The dam material 270, and hence the dam support 275, may be on the substrate 210 and on a side of the underfill 230.

The dam material 270, and hence the dam support 275, may be formed from a material based on any one or more of epoxy, silicone, acrylic, imide, etc. But regardless of the material, in an aspect, the dam support 275 may be more rigid or stiffer than the underfill 230. That is, the dam support 375 may have a higher modulus than the underfill 230. In another aspect, the dam support 275 may have a lower moisture absorption than the underfill 230.

The semiconductor package 200 may further comprise a mold 240 on the underfill 230 and the dam support 275. In an aspect, the mold 240 may be from an epoxy molding compound (EMC). The composition of the EMC may be in tablet form or in powder form. At room temperature, the EMC may be solid. But at high temperatures (e.g., higher than 100° C.), it may be liquid. The mold 240 may encapsulate sides of the die 220. Note that after singulation, sides of the dam support 275, the substrate 210, and the mold 240 may define a side 260 of the semiconductor package 200. Note that the underfill 230 does not reach the side 260 of the semiconductor package 200. This prevents the undercutting of the underfill 230 while enabling the stringent KOZ and better stability during reflow to be maintained.

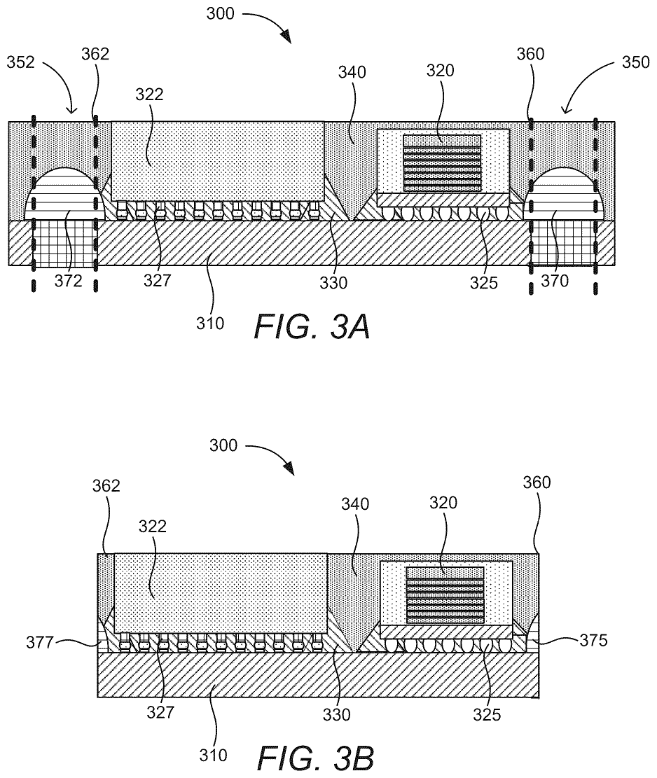

FIGS. 3A-3B illustrate cross-sectional views of another semiconductor package 300 prior to and after singulation in accordance with one or more aspects of the disclosure. These figures suggests that more than one side of a semiconductor package may be provided with the proposed dam structures. The right portions of the semiconductor package 300 in FIGS. 3A and 3B are similar to the semiconductor package 200 (of FIGS. 2A and 2B). That is, the semiconductor package 300 may include a die 320 (e. g, SoC die, DRAM die, etc.) on a substrate 310. The die 320 may include one or more die bumps 325 on a lower surface thereof for electrically connecting the die 320 with the substrate 310. Underfill 330 may fill the space between the die 320 and substrate 310 not occupied by the die bumps 325. Similar to the underfill 230, the underfill 330 may be a capillary underfill, e.g., formed from epoxy resin. The capillary underfill may also include a hardener, a filler (e.g., SiO₂ filler), AND additives including flexible and adhesion promoter.

A dam material 370 may be formed adjacent to the die 320. Prior to singulation (as seen in FIG. 3A), the dam material 370 may be formed on the substrate 310 in both the region of the saw street 350 as well as the region of the semiconductor package 300. After singulation (as seen in FIG. 3B), the dam material that remains in the region of the semiconductor package 300 may become a dam support 375. The dam material 370, and hence the dam support 375, may be on the substrate 310 and on a side of the underfill 330.

The semiconductor package 300 may further comprise a mold 340 on the underfill 330 and the dam support 375. The mold 340 may be formed from materials similar to those of the mold 240. The mold 340 may encapsulate sides of the die 320. After singulation, sides of the dam support 375, the substrate 310, and the mold 340 may define a side 360 of the semiconductor package 300. Again, the underfill 330 does not reach the side 360 of the semiconductor package 300, enabling stringent KOZ to be maintained as well as a better stability during reflow.

Note that in the embodiment illustrated in FIGS. 3A and 3B, more than one die may be included in the semiconductor package 300. Thus, for ease of reference, the die 320, the saw street 350, the side 360, the dam material 370, and the dam support 375 may respectively be referred to as the first die 320, the first saw street 350, the first side 360, the first dam material 370, and the first dam support 375.

The semiconductor package 300 may include a second die 322 on the substrate 310. The second die 322 may be any type of die (SoC, DRAM, etc.). The second die 322 may include one or more second die bumps 327 (also referred to as micro bumps for some dies) on a lower surface thereof for electrically connecting the second die 322 with the substrate 310. The underfill 330 may also fill the space between the second die 322 and substrate 310 not occupied by the second die bumps 327.

A second dam material 372 (same or different material from the first dam material 370) may be formed adjacent to the second die 322. Prior to singulation (as seen in FIG. 3A), the second dam material 372 may be formed on the substrate 310 in both the region of a second saw street 352 as well as the region of the semiconductor package 300. After singulation (as seen in FIG. 3B), the second dam material that remains in the region of the semiconductor package 300 may become a second dam support 377. The second dam material 372, and hence the second dam support 377, may be on the substrate 310 and on a second side of the underfill 330. As seen, the second die 322 may be on the substrate 310 and also between the first die 320 and the second dam support 377.

The mold 240 may also encapsulate sides of the second die 322. After singulation, sides of the second dam support 377, the substrate 310, and the mold 340 may define a second side 362 of the semiconductor package 300. The underfill 330 also may not reach the second side 362 of the semiconductor package 300.

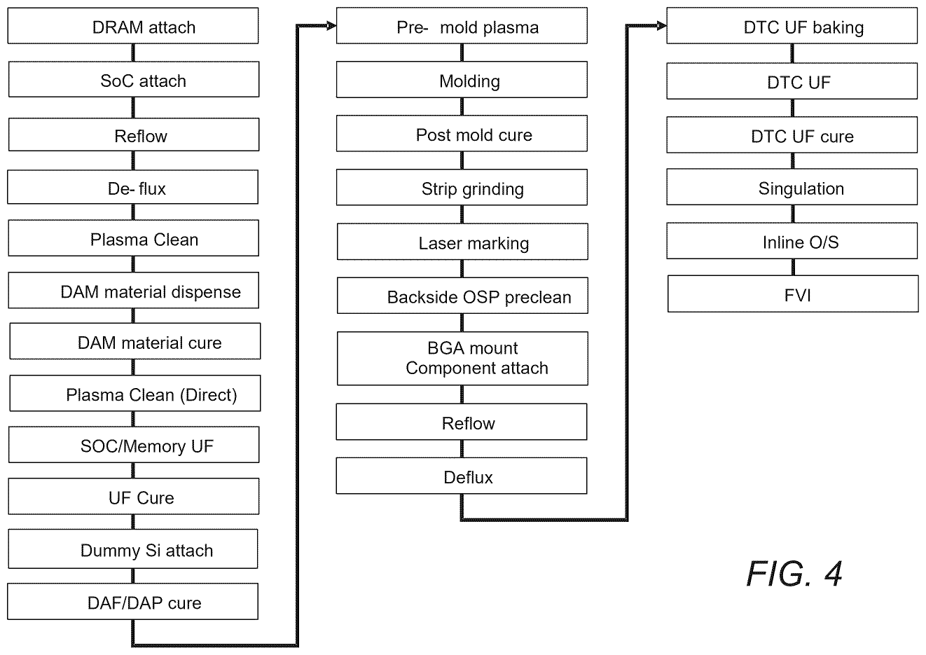

FIG. 4 illustrates a flow of fabrication steps to fabricate a semiconductor package in accordance with one or more aspects of the disclosure.

It should be noted not all steps are required. It should also be noted that unless otherwise specifically indicated, the steps need not be performed in the order shown.

Majority of the steps shown may be referred to as already being known. However, for the purposes of this disclosure, the steps of dispensing the dam material (e.g., dam materials 270, 370) and curing the dam material may be relevant. In these steps, the dam material 270, 370 may be dispensed on the substrate 210, 310 so as to occupy a portion of the region of the substrate 210, 310 as well as the region of the saw street 250, 350, 352.

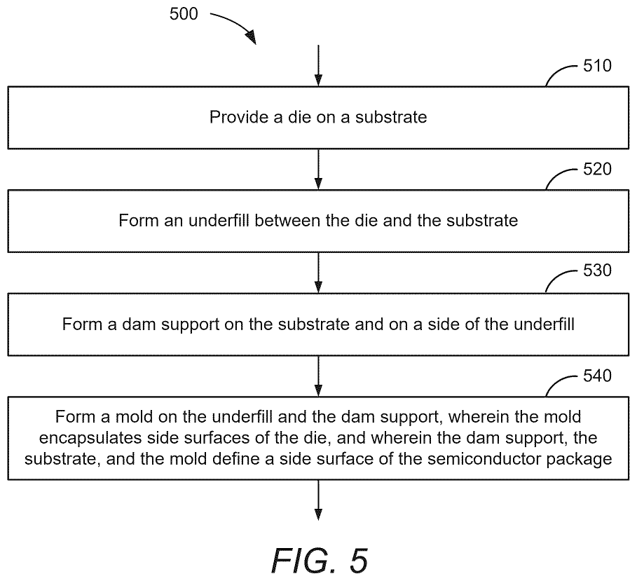

FIG. 5 illustrates a flow chart of an example method 500 of fabricating a semiconductor package, such as the semiconductor packages 200, 300 in accordance with at one or more aspects of the disclosure.

In block 510, a die 220, 320 may be provided on a substrate 210, 310.

In block 520, an underfill (UF) 230, 330 may be formed between the die 220, 320 and the substrate 210, 310.

In block 530, a dam support 275, 375 may be formed on the substrate 210, 310 and on a side of the underfill 230, 330.

In block 540, a mold 240, 340 may be formed on the underfill 230, 330 and the dam support 275, 375. The mold 240, 340 may encapsulate sides of the die 220, 320. Sides of the dam support 275, 375, the substrate 210, 310, and the mold 240, 340 may define a side 260, 360 of the semiconductor package 200, 300.

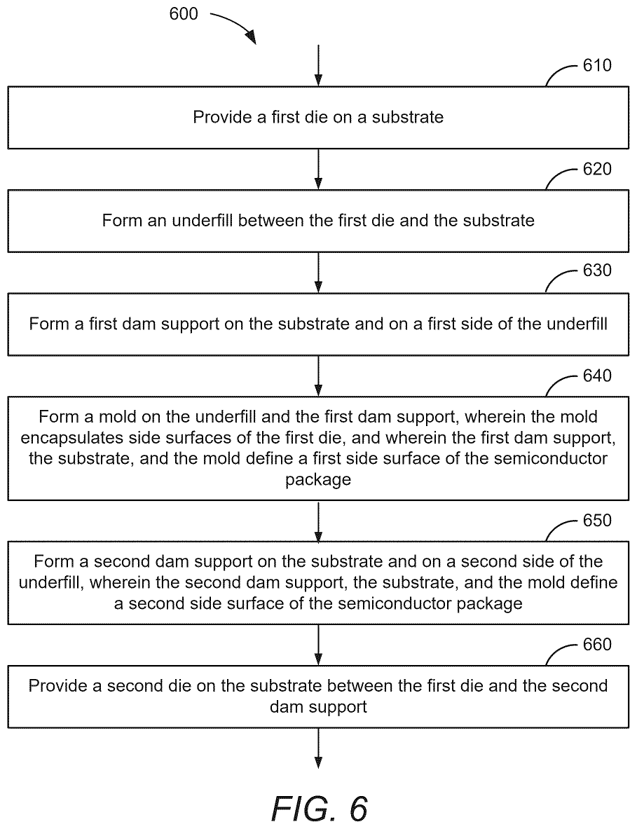

FIG. 6 illustrates a flow chart of an example method 600 of fabricating a semiconductor package, such as the semiconductor package 200, 300 in accordance with at one or more aspects of the disclosure. FIG. 6 may be viewed as being more comprehensive than FIG. 6.

Block 610 may be similar to block 510. That is, in block 610, a die 220, 320 may be provided on a substrate 210, 310.

Block 620 may be similar to block 520. That is, in block 620, an underfill (UF) 230, 330 may be formed between the die 220, 320 and the substrate 210, 310.

Block 630 may be similar to block 530. That is, in block 630, a dam support 275, 375 may be formed on the substrate 210, 310 and on a side of the underfill 230, 330.

Block 640 may be similar to block 540. That is, in block 640, a mold 240, 340 may be formed on the underfill 230, 330 and the dam support 275, 375. The mold 240, 340 may encapsulate sides of the die 220, 320. Sides of the dam support 275, 375, the substrate 210, 310, and the mold 240, 340 may define a side 260, 360 of the semiconductor package 200, 300.

To fabricate the semiconductor package 300 of FIGS. 3A and 3B, blocks 650 and 660 may be implemented. In this instance, the die 320, the dam support 375, the side 360 of the semiconductor package 300, and the side of the underfill 330 may be respectively referred to as the first die 320, the first dam support 375, the first side 360 of the semiconductor package 300, and the first side of the underfill 330.

In block 650, a second dam support 377 may be formed on the substrate 310 and on a second side of the underfill 330. The second dam support 377, the substrate 310, and the mold 340 may define a second side 362 of the semiconductor package 300.

In block 660, a second die 322 may be provided on the substrate 310 between the first die 320 and the second dam support 377. In this instance, the underfill 330 may also be between the second die 322 and the substrate 310.

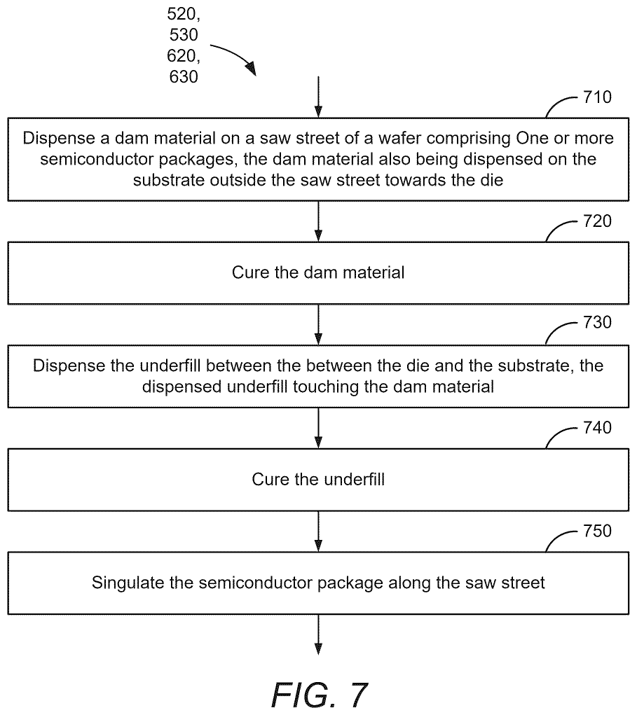

FIG. 7 illustrates an example of a process to implement blocks 520, 620 of forming the underfill and block 530, 630 of forming the dam support of FIGS. 5 and 6.

In block 710, a dam material 270, 370, 372 may be dispensed on a saw street 250, 350, 352 of a substrate comprising one or more semiconductor packages 200, 300. The dam material 270, 370, 372 may also be dispensed on the substrate 210, 310 outside the saw street 250, 350, 352 towards the die 220, 320, 322.

In block 720, the dam material 270, 370, 372 may be cured.

In block 730, the underfill 230, 330 may be dispensed between the die 220, 320, 322 and the substrate 210, 310. The underfill 230, 330 may touch the dam material 270, 370, 372.

In block 740, the underfill 230, 330 may be cured.

In block 750, the semiconductor package 200, 300 may be singulated along the saw street 250, 350, 352.

The following should be noted regarding the flow indicated in FIGS. 5-7. Unless otherwise indicated, the flow of blocks do not necessarily limit the ordering in which the blocks may be performed. In other words, the blocks may be performed in any order that is logical.

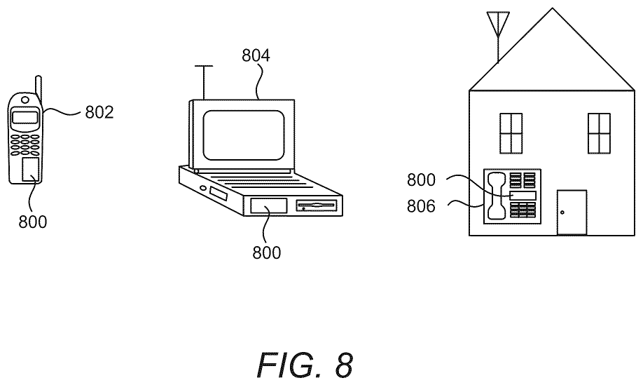

FIG. 8 illustrates various electronic devices 800 that may be integrated with any of the aforementioned semiconductor packages in accordance with various aspects of the disclosure. For example, a mobile phone device 802, a laptop computer device 804, and a fixed location terminal device 806 may each be considered generally user equipment (UE) and may include one or more semiconductor packages (e.g., semiconductor package 200, 300) as described herein. The devices 802, 804, 806 illustrated in FIG. 8 are merely exemplary. Other electronic devices may also include the die packages including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), an Internet of things (IoT) device or any other device that stores or retrieves data or computer instructions or any combination thereof.

The foregoing disclosed devices and functionalities may be designed and configured into computer files (e.g., RTL, GDSII, GERBER, etc.) stored on computer-readable media. Some or all such files may be provided to fabrication handlers who fabricate devices based on such files. Resulting products may include semiconductor wafers that are then cut into semiconductor die and packaged into an antenna on glass device. The antenna on glass device may then be employed in devices described herein.

Implementation examples are described in the following numbered clauses:
Clause 1: A semiconductor package, comprising: a die on a substrate; an underfill (UF) between the die and the substrate; a dam support on the substrate and on a side of the underfill; and a mold on the underfill and the dam support, wherein the mold encapsulates sides of the die, and wherein sides of the dam support, the substrate, and the mold define a side of the semiconductor package.
Clause 2: The semiconductor package of clause 1, wherein the dam support has a higher modulus than the underfill.
Clause 3: The semiconductor package of any of clauses 1-2, wherein the dam support has a lower moisture absorption than the underfill.
Clause 4: The semiconductor package of any of clauses 1-3, wherein the dam support is formed from a material based on any one or more of epoxy, silicone, acrylic, and imide.
Clause 5: The semiconductor package of any of clauses 1-4, wherein the underfill does not reach the side of the semiconductor package.
Clause 6: The semiconductor package of any of clauses 1-5, wherein the dam support is a first dam support, the side of the semiconductor package is a first side of the semiconductor package, and the side of the underfill is a first side of the underfill, wherein the semiconductor package further comprises: a second dam support on the substrate and on a second side of the underfill, and wherein the second dam support, the substrate, and the mold define a second side of the semiconductor package.
Clause 7: The semiconductor package of clause 6, wherein the die is a first die, wherein the semiconductor package further comprises: a second die on the substrate between the first die and the second dam support, and wherein the underfill is also between the second die and the substrate.
Clause 8: The semiconductor package of any of clauses 1-7, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.
Clause 9: A method of fabricating a semiconductor package, the method comprising: providing a die on a substrate; forming an underfill (UF) between the die and the substrate; forming a dam support on the substrate and on a side of the underfill; and forming a mold on the underfill and the dam support, wherein the mold encapsulates sides of the die, and wherein sides of the dam support, the substrate, and the mold define a side of the semiconductor package.
Clause 10: The method of clause 9, wherein the dam support has a higher modulus than the underfill.
Clause 11: The method of any of clauses 9-10, wherein the dam support has a lower moisture absorption than the underfill.
Clause 12: The method of any of clauses 9-11, wherein the dam support is formed from a material based on any one or more of epoxy, silicone, acrylic, and imide.
Clause 13: The method of any of clauses 9-12, wherein the underfill does not reach the side of the semiconductor package.
Clause 14: The method of any of clauses 9-13, wherein the dam support is a first dam support, the side of the semiconductor package is a first side of the semiconductor package, and the side of the underfill is a first side of the underfill, wherein the method further comprises: forming a second dam support on the substrate and on a second side of the underfill, and wherein the second dam support, the substrate, and the mold define a second side of the semiconductor package.
Clause 15: The method of clause 14, wherein the die is a first die, wherein the method further comprises: providing a second die on the substrate between the first die and the second dam support, and wherein the underfill is also between the second die and the substrate.
Clause 16: The method of any of clauses 9-15, wherein forming the underfill and forming a dam support comprise: dispensing a dam material on a saw street of the substrate comprising one or more of semiconductor packages, the dam material also being dispensed on the substrate outside the saw street towards the die; curing the dam material; dispensing the underfill between the die and the substrate, the underfill touching the dam material; curing the underfill; and singulating the semiconductor package along the saw street.

As used herein, the terms “user equipment” (or “UE”), “user device,” “user terminal,” “client device,” “communication device,” “wireless device,” “wireless communications device,” “handheld device,” “mobile device,” “mobile terminal,” “mobile station,” “handset,” “access terminal,” “subscriber device,” “subscriber terminal,” “subscriber station,” “terminal,” and variants thereof may interchangeably refer to any suitable mobile or stationary device that can receive wireless communication and/or navigation signals. These terms include, but are not limited to, a music player, a video player, an entertainment unit, a navigation device, a communications device, a smartphone, a personal digital assistant, a fixed location terminal, a tablet computer, a computer, a wearable device, a laptop computer, a server, an automotive device in an automotive vehicle, and/or other types of portable electronic devices typically carried by a person and/or having communication capabilities (e.g., wireless, cellular, infrared, short-range radio, etc.). These terms are also intended to include devices which communicate with another device that can receive wireless communication and/or navigation signals such as by short-range wireless, infrared, wireline connection, or other connection, regardless of whether satellite signal reception, assistance data reception, and/or position-related processing occurs at the device or at the other device. In addition, these terms are intended to include all devices, including wireless and wireline communication devices, that are able to communicate with a core network via a radio access network (RAN), and through the core network the UEs can be connected with external networks such as the Internet and with other UEs. Of course, other mechanisms of connecting to the core network and/or the Internet are also possible for the UEs, such as over a wired access network, a wireless local area network (WLAN) (e.g., based on IEEE 802.11, etc.) and so on. UEs can be embodied by any of a number of types of devices including but not limited to printed circuit (PC) cards, compact flash devices, external or internal modems, wireless or wireline phones, smartphones, tablets, tracking devices, asset tags, and so on. A communication link through which UEs can send signals to a RAN is called an uplink channel (e.g., a reverse traffic channel, a reverse control channel, an access channel, etc.). A communication link through which the RAN can send signals to UEs is called a downlink or forward link channel (e.g., a paging channel, a control channel, a broadcast channel, a forward traffic channel, etc.). As used herein the term traffic channel (TCH) can refer to either an uplink/reverse or downlink/forward traffic channel.

The wireless communication between electronic devices can be based on different technologies, such as code division multiple access (CDMA), W-CDMA, time division multiple access (TDMA), frequency division multiple access (FDMA), Orthogonal Frequency Division Multiplexing (OFDM), Global System for Mobile Communications (GSM), 3GPP Long Term Evolution (LTE), 5G New Radio, Bluetooth (BT), Bluetooth Low Energy (BLE), IEEE 802.11 (WiFi), and IEEE 802.15.4 (Zigbee/Thread) or other protocols that may be used in a wireless communications network or a data communications network. Bluetooth Low Energy (also known as Bluetooth LE, BLE, and Bluetooth Smart) is a wireless personal area network technology designed and marketed by the Bluetooth Special Interest Group intended to provide considerably reduced power consumption and cost while maintaining a similar communication range. BLE was merged into the main Bluetooth standard in 2010 with the adoption of the Bluetooth Core Specification Version 4.0 and updated in Bluetooth 5.

It should be noted that the terms “connected,” “coupled,” or any variant thereof, mean any connection or coupling, either direct or indirect, between elements, and can encompass a presence of an intermediate element between two elements that are “connected” or “coupled” together via the intermediate element unless the connection is expressly disclosed as being directly connected.

Any reference herein to an element using a designation such as “first,” “second,” and so forth does not limit the quantity and/or order of those elements. Rather, these designations are used as a convenient method of distinguishing between two or more elements and/or instances of an element. Also, unless stated otherwise, a set of elements can comprise one or more elements.

Nothing stated or illustrated depicted in this application is intended to dedicate any component, action, feature, benefit, advantage, or equivalent to the public, regardless of whether the component, action, feature, benefit, advantage, or the equivalent is recited in the claims.

In the detailed description above it can be seen that different features are grouped together in examples. This manner of disclosure should not be understood as an intention that the claimed examples have more features than are explicitly mentioned in the respective claim. Rather, the disclosure may include fewer than all features of an individual example disclosed. Therefore, the following claims should hereby be deemed to be incorporated in the description, wherein each claim by itself can stand as a separate example. Although each claim by itself can stand as a separate example, it should be noted that—although a dependent claim can refer in the claims to a specific combination with one or one or more claims—other examples can also encompass or include a combination of said dependent claim with the subject matter of any other dependent claim or a combination of any feature with other dependent and independent claims. Such combinations are proposed herein, unless it is explicitly expressed that a specific combination is not intended. Furthermore, it is also intended that features of a claim can be included in any other independent claim, even if said claim is not directly dependent on the independent claim.

It should furthermore be noted that methods, systems, and apparatus disclosed in the description or in the claims can be implemented by a device comprising means for performing the respective actions and/or functionalities of the methods disclosed.

Furthermore, in some examples, an individual action can be subdivided into one or more sub-actions or contain one or more sub-actions. Such sub-actions can be contained in the disclosure of the individual action and be part of the disclosure of the individual action.

While the foregoing disclosure shows illustrative examples of the disclosure, it should be noted that various changes and modifications could be made herein without departing from the scope of the disclosure as defined by the appended claims. The functions and/or actions of the method claims in accordance with the examples of the disclosure described herein need not be performed in any particular order. Additionally, well-known elements will not be described in detail or may be omitted so as to not obscure the relevant details of the aspects and examples disclosed herein. Furthermore, although elements of the disclosure may be described or claimed in the singular, the plural is contemplated unless limitation to the singular is explicitly stated.

What is claimed is:

1. A semiconductor package, comprising:
a die on a substrate;
an underfill (UF) between the die and the substrate;
a dam support on the substrate and on a side of the underfill; and
a mold on the underfill and the dam support,
wherein the mold encapsulates sides of the die, and
wherein sides of the dam support, the substrate, and the mold define a side of the semiconductor package.

2. The semiconductor package of claim 1, wherein the dam support has a higher modulus than the underfill.

3. The semiconductor package of claim 1, wherein the dam support has a lower moisture absorption than the underfill.

4. The semiconductor package of claim 1, wherein the dam support is formed from a material based on any one or more of epoxy, silicone, acrylic, and imide.

5. The semiconductor package of claim 1, wherein the underfill does not reach the side of the semiconductor package.

6. The semiconductor package of claim 1,
wherein the dam support is a first dam support, the side of the semiconductor package is a first side of the semiconductor package, and the side of the underfill is a first side of the underfill,
wherein the semiconductor package further comprises:
a second dam support on the substrate and on a second side of the underfill, and
wherein the second dam support, the substrate, and the mold define a second side of the semiconductor package.

7. The semiconductor package of claim 6,
wherein the die is a first die,
wherein the semiconductor package further comprises:
a second die on the substrate between the first die and the second dam support, and
wherein the underfill is also between the second die and the substrate.

8. The semiconductor package of claim 1, wherein the semiconductor package is incorporated into an apparatus selected from the group consisting of a music player, a video player, an entertainment unit, a navigation device, a communications device, a mobile device, a mobile phone, a smartphone, a personal digital assistant, a fixed location terminal, a tablet computer, a computer, a wearable device, an Internet of things (IoT) device, a laptop computer, a server, and a device in an automotive vehicle.

9. A method of fabricating a semiconductor package, the method comprising:
providing a die on a substrate;
forming an underfill (UF) between the die and the substrate;
forming a dam support on the substrate and on a side of the underfill; and
forming a mold on the underfill and the dam support,
wherein the mold encapsulates sides of the die, and
wherein sides of the dam support, the substrate, and the mold define a side of the semiconductor package.

10. The method of claim 9, wherein the dam support has a higher modulus than the underfill.

11. The method of claim 9, wherein the dam support has a lower moisture absorption than the underfill.

12. The method of claim 9, wherein the dam support is formed from a material based on any one or more of epoxy, silicone, acrylic, and imide.

13. The method of claim 9, wherein the underfill does not reach the side of the semiconductor package.

14. The method of claim 9,
wherein the dam support is a first dam support, the side of the semiconductor package is a first side of the semiconductor package, and the side of the underfill is a first side of the underfill,
wherein the method further comprises:
forming a second dam support on the substrate and on a second side of the underfill, and
wherein the second dam support, the substrate, and the mold define a second side of the semiconductor package.

15. The method of claim 14,
wherein the die is a first die,
wherein the method further comprises:
providing a second die on the substrate between the first die and the second dam support, and
wherein the underfill is also between the second die and the substrate.

16. The method of claim 9, wherein forming the underfill and forming a dam support comprise:
dispensing a dam material on a saw street of the substrate comprising one or more semiconductor packages, the dam material also being dispensed on the substrate outside the saw street towards the die;
curing the dam material;
dispensing the underfill between the die and the substrate, the underfill touching the dam material;
curing the underfill; and
singulating the semiconductor package along the saw street.
